(19) United States
(12) Patent Application Publication
(10) Pub. No.: US 2026/0363121 A1
(43) Pub. Date: Nov. 12, 2026

(54) INSULATING SUBSTRATE AND SEMICONDUCTOR DEVICE

(71) Applicant: Mitsubishi Electric Corporation, Tokyo (JP)

(72) Inventors: Katsuhiko KONDO, Tokyo (JP); Yuji IMOTO, Tokyo (JP)

(73) Assignee: Mitsubishi Electric Corporation, Tokyo (JP)

(21) Appl. No.: 19/121,620

(22) PCT Filed: Jan. 12, 2023
(86) PCT No.: PCT/JP2023/000594

§ 371 Date: Apr. 16, 2025

(51) Int. Cl. H10W 70/692

(52) U.S. Cl. CPC H10W 70/692

(57) ABSTRACT

It is an object to provide technology capable of suppressing reduction in appearance quality and an insulation failure, such as a short circuit, between circuit patterns attributable to a residue of plating of a semiconductor device. An insulating substrate includes: a ceramic substrate; and a circuit pattern which is joined to a front surface of the ceramic substrate and to which a semiconductor element is to be mounted. An outer peripheral portion of the circuit pattern has, on a side of a rear surface thereof joined to the ceramic substrate, an excavated portion not being in contact with the front surface of the ceramic substrate.

### TECHNICAL FIELD

The present disclosure relates to insulating substrates and semiconductor devices.

### BACKGROUND ART

For example, Patent Document 1 proposes a semiconductor device having improved reliability of joining of circuit patterns and semiconductor elements.

An insulating substrate mounted to the semiconductor device is subjected to a plating step to join the circuit patterns formed over a front surface of a ceramic substrate of the insulating substrate and the semiconductor elements with solder and a de-plating step. In the plating step, the entire insulating substrate is plated. In the de-plating step, only portions necessary for solder joining are masked with resist materials, plating in a portion not required to be plated is dissolved in a de-plating solution for removal, and then a residue of plating is removed by air blowing.

### PRIOR ART DOCUMENTS

### Patent Document

Patent Document 1: Japanese Patent Application Laid-Open No. 2007-311527

### SUMMARY

### Problem to be Solved by the Invention

During manufacture of the circuit patterns, however, the circuit patterns sometimes have minute roll-offs on sides of outer peripheries of their interfaces with the ceramic substrate. The roll-offs are less likely to be exposed to wind by air blowing, so that the residue of plating is likely to be left at the roll-offs even after the de-plating step. When the semiconductor device is manufactured with the residue of plating being left, the residue of plating accumulated at the roll-offs might flow due to a thermal load during soldering and a flow of a sealing resin to reduce appearance quality of the semiconductor device. Furthermore, when the residue of plating flows to traverse between the circuit patterns, an insulation failure, such as a short circuit, might occur between the circuit patterns.

In technology disclosed in Patent Document 1, outer peripheral portions of the circuit patterns have braze-pooling recesses, but a function of the braze-pooling recesses is limited to a function of pooling braze materials used for joining of the semiconductor elements and the circuit patterns, and a problem attributable to the residue of plating is not taken into account.

It is thus an object of the present disclosure to provide technology capable of suppressing reduction in appearance quality and an insulation failure, such as a short circuit, between circuit patterns attributable to a residue of plating of a semiconductor device.

### Means to Solve the Problem

An insulating substrate according to the present disclosure includes: a ceramic substrate; and a circuit pattern which is joined to a front surface of the ceramic substrate and to which a semiconductor element is to be mounted, wherein an outer peripheral portion of the circuit pattern has, on a side of a rear surface thereof joined to the ceramic substrate, an excavated portion not being in contact with the front surface of the ceramic substrate.

### Effects of the Invention

According to the present disclosure, in a de-plating step performed before joining of the circuit pattern and the semiconductor element, a de-plating solution is likely to penetrate to a side of the rear surface of the outer peripheral portion of the circuit pattern, and exposure to wind by air blowing to remove a residue of plating is improved, so that a residue of unnecessary plating can more effectively be removed. Reduction in appearance quality and an insulation failure, such as a short circuit, between circuit patterns of a semiconductor device attributable to the residue of plating can thereby be suppressed.

These and other objects, features, aspects and advantages of the present disclosure will become more apparent from the following detailed description when taken in conjunction with the accompanying drawings.

### BRIEF DESCRIPTION OF DRAWINGS

FIG. 1 is a cross-sectional view of a semiconductor device according to Embodiment 1.

FIG. 2 is a cross-sectional view of a semiconductor device according to Embodiment 2.

FIG. 3 is a cross-sectional view of a semiconductor device according to Embodiment 3.

FIG. 4 is a cross-sectional view of a semiconductor device according to Modification 1 of Embodiment 3.

FIG. 5 is a cross-sectional view of a semiconductor device according to Modification 2 of Embodiment 3.

FIG. 6 includes a top view from above semiconductor elements, a cross-sectional view taken along the line A-A, and a cross-sectional view taken along the line B-B of a semiconductor device according to Embodiment 4.

FIG. 7 is a top view from above a semiconductor element of a portion of a semiconductor device according to Modification 1 of Embodiment 4.

FIG. 8 is a top view from above a semiconductor element of a portion of a semiconductor device according to Modification 2 of Embodiment 4.

FIG. 9 is a top view from above a semiconductor element of a portion of a semiconductor device according to Modification 3 of Embodiment 4.

### DESCRIPTION OF EMBODIMENTS

### Embodiment 1

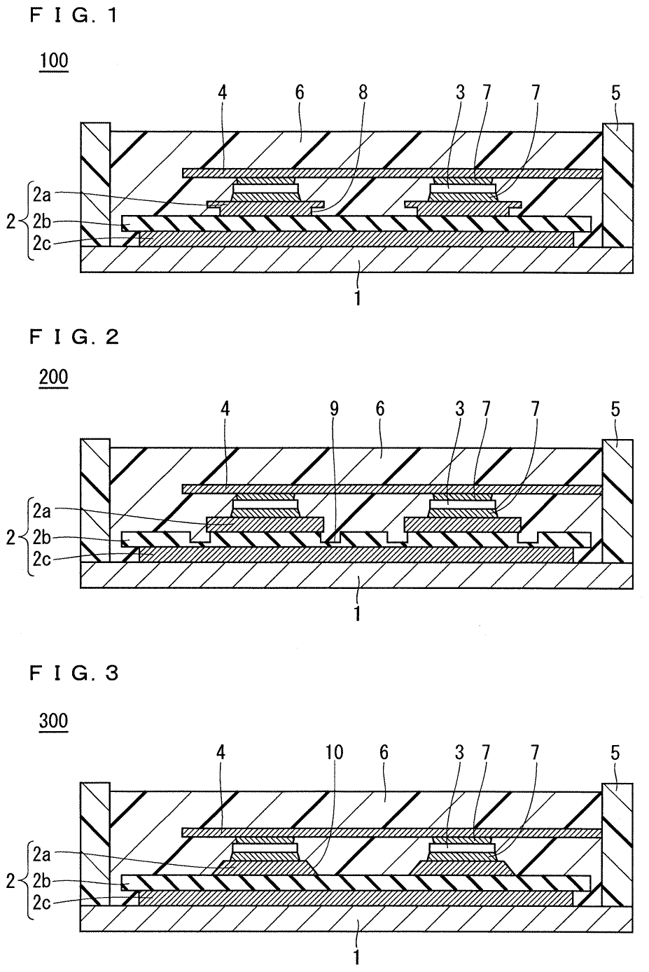

Embodiment 1 will be described below with reference to the drawings. FIG. 1 is a cross-sectional view of a semiconductor device 100 according to Embodiment 1.

As illustrated in FIG. 1, the semiconductor device 100 includes a base plate 1, an insulating substrate 2, semiconductor elements 3, a main terminal 4, a resin case 5, and a sealing resin 6.

The base plate 1 is rectangular in top view and is formed of a material having relatively high thermal conductivity, such as copper, a copper alloy, aluminum, and an aluminum alloy.

The insulating substrate 2 includes front circuit patterns 2a, a ceramic substrate 2b, and a rear circuit pattern 2c. The ceramic substrate 2b is formed of ceramics, such as Al₂O₃, AlN, and Si₃N₄. The front circuit patterns 2a and the rear circuit pattern 2c are formed of metal containing Cu as a major component, for example. The front circuit patterns 2a and the rear circuit pattern 2c are joined respectively to a front surface and a rear surface of the ceramic substrate 2b with braze materials (not illustrated) and the like. The front circuit patterns 2a are circuit patterns to which the semiconductor elements 3 are to be mounted and have selectively been formed. That is to say, the number of front circuit patterns 2a is two or more, and circuits necessary for the semiconductor device 100 have been formed therein.

Rear electrodes (e.g., collector electrodes) of the semiconductor elements 3 are joined onto the front circuit patterns 2a via joining materials 7 formed of lead-free solder, such as Sn—Ag-based solder, to mount the semiconductor elements 3. The semiconductor elements 3 are power semiconductor elements formed of Si, SiC, or GaN, for example, and it is important to secure high heat dissipation as the power semiconductor elements generate high temperature heat during operation. While two semiconductor elements 3 are illustrated in FIG. 1, the number of semiconductor elements 3 is not limited to two and is only required to be one or more.

The main terminal 4 containing Cu as a major component is joined to front electrodes (e.g., emitter electrodes or gate electrodes) of the semiconductor elements 3 via joining materials 7 to form various types of wiring to thereby form circuits necessary for the semiconductor device 100.

The resin case 5 is formed of a high heat resistant resin, such as PPS, into a rectangular frame in top view. The resin case 5 is fixed to an outer peripheral portion of the base plate 1 with an adhesive (not illustrated) to surround the circuits including the semiconductor elements 3. The resin case 5 is filled with the sealing resin 6, such as an epoxy resin, to protect the circuits including the semiconductor elements 3.

A problem arising during manufacture of the insulating substrate 2 will be described next. A step of manufacturing the insulating substrate 2 includes a plating step to join the front circuit patterns 2a and the semiconductor elements 3 with solder and a de-plating step. In the plating step, the entire insulating substrate 2 is plated. In the de-plating step, only portions necessary for solder joining are masked with resist materials, plating in a portion not required to be plated is dissolved in a de-plating solution for removal, and then a residue of plating is removed by air blowing.

During manufacture of the front circuit patterns 2a, the front circuit patterns 2a sometimes have minute roll-offs on sides of outer peripheries of their interfaces with the ceramic substrate 2b. The roll-offs are less likely to be exposed to wind by air blowing, so that the residue of plating is likely to be left at the roll-offs even after the de-plating step. When the semiconductor device 100 is manufactured with the residue of plating being left, the residue of plating accumulated at the roll-offs might flow due to a thermal load during soldering and a flow of the sealing resin 6 to reduce appearance quality of the semiconductor device. Furthermore, when the residue of plating flows to traverse between the front circuit patterns 2a, an insulation failure, such as a short circuit, might occur between the front circuit patterns 2a.

In contrast, in Embodiment 1, as illustrated in FIG. 1, outer peripheral portions of the front circuit patterns 2a have, on sides of rear surfaces thereof joined to the ceramic substrate 2b, excavated portions 8 not being in contact with the front surface of the ceramic substrate 2b. The excavated portions 8 are formed over the entire outer peripheral portions of the front circuit patterns 2a.

The excavated portions 8 are provided in portions where the minute roll-offs are formed as openings larger than the roll-offs, so that the de-plating solution can sufficiently penetrate to the sides of the rear surfaces of the outer peripheral portions of the front circuit patterns 2a, and exposure to wind by air blowing can be improved. The residue of plating can thereby be reduced.

As described above, the semiconductor device 100 according to Embodiment 1 includes the insulating substrate 2, the semiconductor elements 3 mounted to the front surfaces of the front circuit patterns 2a, and the base plate 1 joined to a side of the rear surface of the ceramic substrate 2b.

The insulating substrate 2 includes the ceramic substrate 2b and the front circuit patterns 2a which are joined to the front surface of the ceramic substrate 2b and to which the semiconductor elements 3 are to be mounted. The outer peripheral portions of the front circuit patterns 2a have, on the sides of the rear surfaces thereof joined to the ceramic substrate 2b, the excavated portions 8 not being in contact with the front surface of the ceramic substrate 2b.

Thus, in the de-plating step performed before joining of the front circuit patterns 2a and the semiconductor elements 3, the de-plating solution is likely to penetrate to the sides of the rear surfaces of the outer peripheral portions of the front circuit patterns 2a, and exposure to wind by air blowing to remove the residue of plating is improved, so that a residue of unnecessary plating can more effectively be removed. Reduction in appearance quality and the insulation failure, such as the short circuit, between the front circuit patterns 2a of the semiconductor device 100 attributable to the residue of plating can thereby be suppressed.

Durability and yield of the insulating substrate 2 and the semiconductor device 100 can thereby be improved.

### Embodiment 2

A semiconductor device 200 according to Embodiment 2 will be described next. FIG. 2 is a cross-sectional view of the semiconductor device 200 according to Embodiment 2. In Embodiment 2, the same components as those described in Embodiment 1 bear the same reference signs as those of the same components, and description thereof is omitted.

As illustrated in FIG. 2, in Embodiment 2, the front circuit patterns 2a do not have the excavated portions 8, and the ceramic substrate 2b has excavated portions 9.

The excavated portions 9 are formed in portions of the ceramic substrate 2b adjacent to the outer peripheral portions of the front circuit patterns 2a to be recessed downwards. Specifically, the excavated portions 9 are formed from portions facing the entire outer peripheral portions of the front circuit patterns 2a toward an outer periphery of the ceramic substrate 2b. The excavated portions 9 are formed so that the outer peripheral portions of the front circuit patterns 2a are not in contact with the ceramic substrate 2b.

The excavated portions 9 are provided in portions adjacent to the portions where the minute roll-offs are formed as openings larger than the roll-offs, so that the de-plating solution can sufficiently penetrate to the sides of the rear surfaces of the outer peripheral portions of the front circuit patterns 2a, and exposure to wind by air blowing can be improved. The residue of plating can thereby be reduced.

As described above, in the semiconductor device 200 according to Embodiment 2, the insulating substrate 2 includes the ceramic substrate 2b and the front circuit patterns 2a which are joined to the front surface of the ceramic substrate 2b and to which the semiconductor elements 3 are to be mounted. The portions of the ceramic substrate 2b adjacent to the outer peripheral portions of the front circuit patterns 2a have the excavated portions 9 recessed downwards.

Thus, in the de-plating step performed before joining of the front circuit patterns 2a and the semiconductor elements 3, the de-plating solution is likely to penetrate to the sides of the rear surfaces of the outer peripheral portions of the front circuit patterns 2a, and exposure to wind by air blowing to remove the residue of plating is improved, so that the residue of unnecessary plating can more effectively be removed. Reduction in appearance quality and the insulation failure, such as the short circuit, between the front circuit patterns 2a of the semiconductor device 200 attributable to the residue of plating can thereby be suppressed.

### Embodiment 3

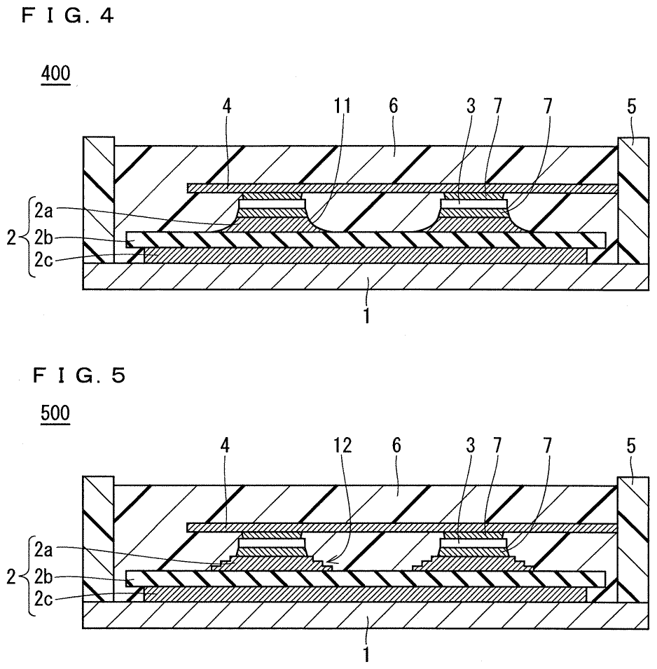

A semiconductor device 300 according to Embodiment 3 will be described next. FIG. 3 is a cross-sectional view of the semiconductor device 300 according to Embodiment 3. In Embodiment 3, the same components as those described in Embodiments 1 and 2 bear the same reference signs as those of the same components, and description thereof is omitted.

As illustrated in FIG. 3, in Embodiment 3, the excavated portions 8 and 9 are not formed, and the outer peripheral portions of the front circuit patterns 2a have tapered shapes 10 so that the front circuit patterns 2a are tapered from the rear surfaces thereof joined to the ceramic substrate 2b to the front surfaces thereof to which the semiconductor elements 3 are mounted. The tapered shapes 10 are formed over the entire outer peripheral portions of the front circuit patterns 2a.

The outer peripheral portions of the front circuit patterns 2a have the tapered shapes 10, so that outer peripheral surfaces of the front circuit patterns 2a face upwards, the de-plating solution is likely to penetrate to the entire outer peripheral portions of the front circuit patterns 2a, and exposure to wind by air blowing to remove the residue of plating is improved, so that the residue of unnecessary plating can more effectively be removed.

As described above, in the semiconductor device 300 according to Embodiment 3, the insulating substrate 2 includes the ceramic substrate 2b and the front circuit patterns 2a which are joined to the front surface of the ceramic substrate 2b and to which the semiconductor elements 3 are to be mounted. The outer peripheral portions of the front circuit patterns 2a have the tapered shapes 10 so that the front circuit patterns 2a are tapered from the rear surfaces thereof joined to the ceramic substrate 2b to the front surfaces thereof to which the semiconductor elements 3 are to be mounted.

Thus, in the de-plating step performed before joining of the front circuit patterns 2a and the semiconductor elements 3, the de-plating solution is likely to penetrate to the entire outer peripheral portions of the front circuit patterns 2a, and exposure to wind by air blowing to remove the residue of plating is improved, so that the residue of unnecessary plating can more effectively be removed. Reduction in appearance quality and the insulation failure, such as the short circuit, between the front circuit patterns 3a of the semiconductor device 300 attributable to the residue of plating can thereby be suppressed.

### Modifications of Embodiment 3

Modifications 1 and 2 of Embodiment 3 will be described next. FIG. 4 is a cross-sectional view of a semiconductor device 400 according to Modification 1 of Embodiment 3. FIG. 5 is a cross-sectional view of a semiconductor device 500 according to Modification 2 of Embodiment 3.

As illustrated in FIG. 4, tapered shapes 11 of the outer peripheral portions of the front circuit patterns 2a may be curved shapes. As illustrated in FIG. 5, tapered shapes 12 of the outer peripheral portions of the front circuit patterns 2a may be stepped shapes. A similar effect to that obtained in a case of Embodiment 3 is obtained in each of these cases.

### Embodiment 4

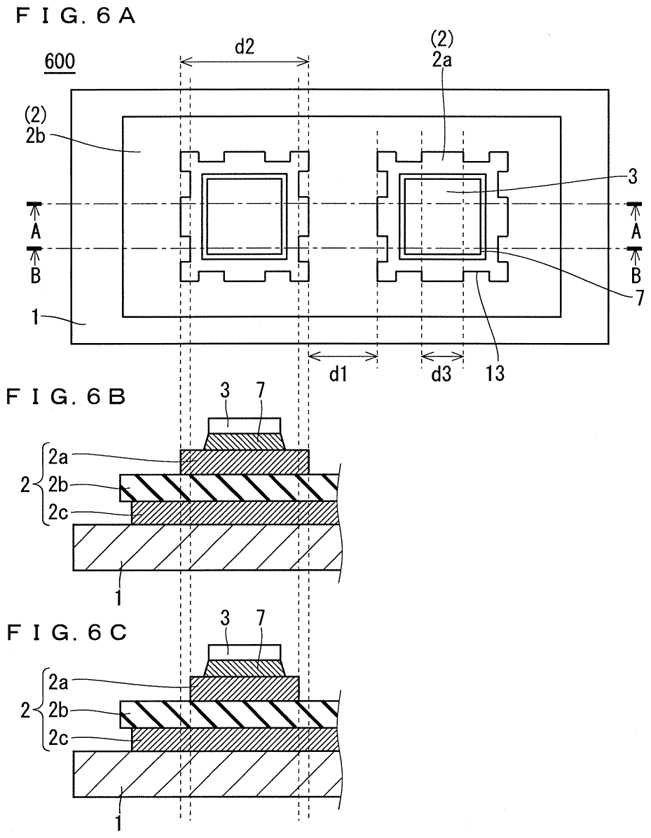

A semiconductor device 600 according to Embodiment 4 will be described next. FIG. 6(a) is a top view from above the semiconductor elements 3 of the semiconductor device 600 according to Embodiment 4. FIG. 6(b) is a cross-sectional view taken along the line A-A of FIG. 6(a), and FIG. 6(c) is a cross-sectional view taken along the line B-B of FIG. 6(a). In Embodiment 4, the same components as those described in Embodiments 1 to 3 bear the same reference signs as those of the same components, and description thereof is omitted.

As illustrated in FIG. 6(a), in Embodiment 4, cutout portions 13 are formed in place of the excavated portions 8 and 9 and the tapered shapes 10, 11, and 12. The cutout portions 13 are a plurality of cutout portions 13 successively formed over the entire outer peripheral portions of the front circuit patterns 2a. Specifically, the cutout portions 13 are each rectangular in top view, and each side of the front circuit patterns 2a has two cutout portions 13.

As illustrated in FIG. 6(a), 6(b), and 6(c), the cutout portions 13 are each formed to have the same thickness as each of the front circuit patterns 2a. As illustrated in FIG. 6(a) and 6(b), a portion of each of the front circuit patterns 2a not having the cutout portions 13 has the same width d2 as a conventional structure not having the cutout portions 13.

In the conventional structure not having the cutout portions 13, each side in the outer peripheral portions of the front circuit patterns 2a has the width d2, and a residue of plating having a length corresponding to the width d2 might be accumulated and flow to traverse between adjacent front circuit patterns 2a by a length d1 during manufacture of the semiconductor device, so that the residue of plating might cause the insulation failure, such as the short circuit, between the front circuit patterns 2a. d2>d1 herein holds true.

In contrast, in Embodiment 4, a width d3 of each side in the outer peripheral portions of the front circuit patterns 2a as a length between adjacent cutout portions 1 in the outer peripheral portions of the front circuit patterns 2a is sufficiently shorter than the length dl between adjacent front circuit patterns 2a (d3<d1). Thus, even when a residue of plating having a length corresponding to the width d3 is accumulated and flows to traverse between the front circuit patterns 2a by the length dl during manufacture of the semiconductor device 600, contact of the residue of plating with an adjacent front circuit pattern 2a can be suppressed.

As described above, in the semiconductor device 600 according to Embodiment 4, the insulating substrate 2 includes the ceramic substrate 2b and the front circuit patterns 2a which are joined to the front surface of the ceramic substrate 2b and to which the semiconductor elements 3 are to be mounted. The outer peripheral portions of the front circuit patterns 2a have the plurality of successive cutout portions 13. The cutout portions 13 are each rectangular in top view.

Thus, even when the residue of plating flows to traverse between the adjacent front circuit patterns 2a during manufacture of the semiconductor device 600, contact of the residue of plating with the adjacent front circuit pattern 2a can be suppressed. Reduction in appearance quality and the insulation failure, such as the short circuit, between the front circuit patterns 2a of the semiconductor device 600 attributable to the residue of plating can thereby be suppressed.

### Modifications of Embodiment 4

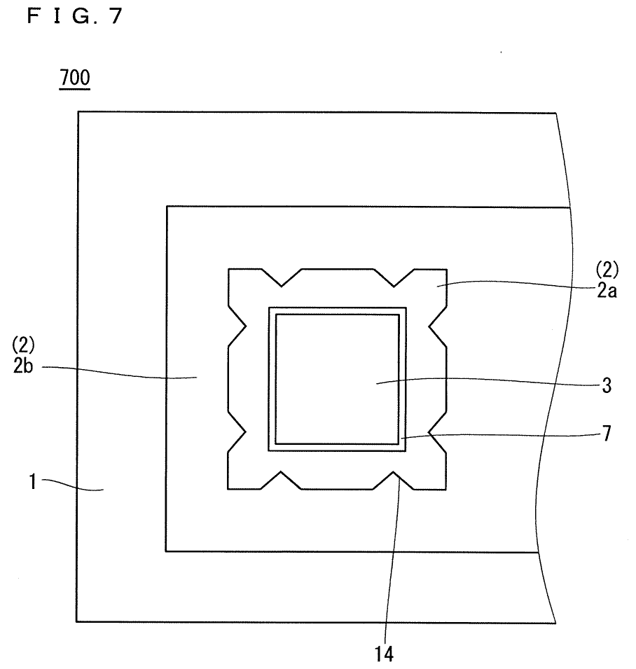

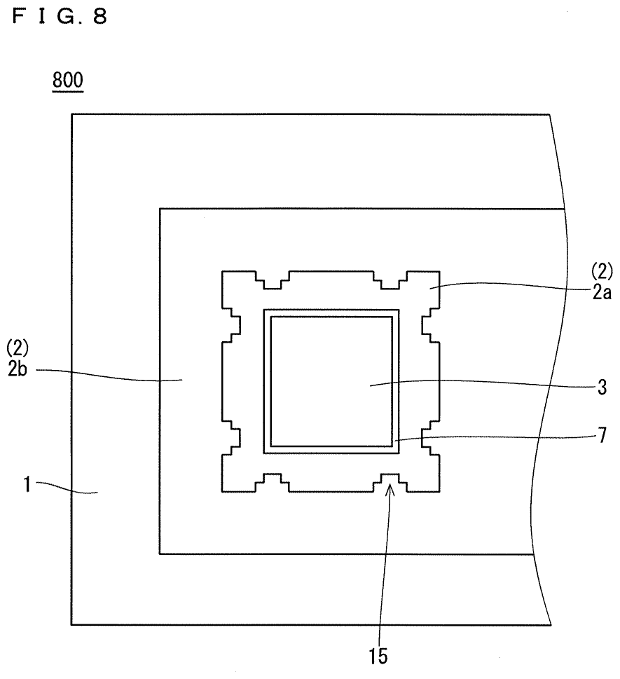

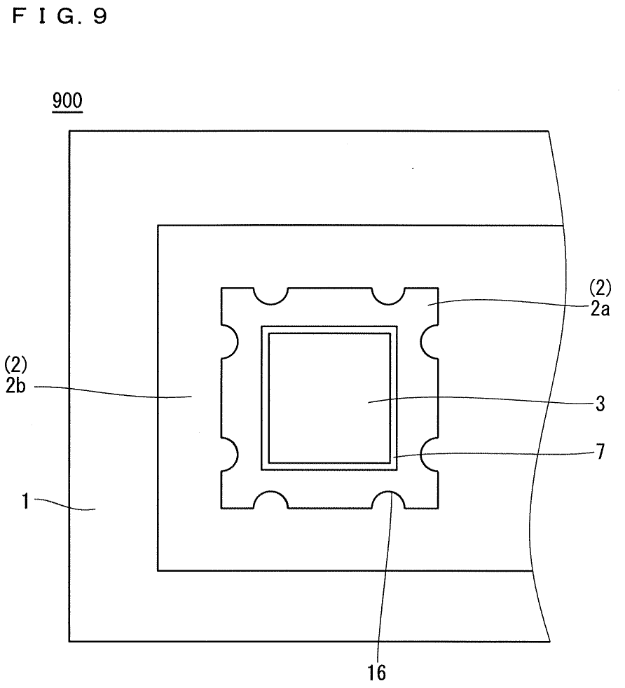

Modifications 1 to 3 of Embodiment 4 will be described next. FIG. 7 is a top view from above a semiconductor element 3 of a portion of a semiconductor device 700 according to Modification 1 of Embodiment 4. FIG. 8 is a top view from above a semiconductor element 3 of a portion of a semiconductor device 800 according to Modification 2 of Embodiment 4. FIG. 9 is a top view from above a semiconductor element 3 of a portion of a semiconductor device 900 according to Modification 3 of Embodiment 4.

As illustrated in FIG. 7, cutout portions 14 may each be triangular in top view. As illustrated in FIG. 8, cutout portions 15 may each be stepped in top view. As illustrated in FIG. 9, cutout portions 16 may each be arcuate in top view. A similar effect to that obtained in a case of Embodiment 4 is obtained in each of these cases.

While the present disclosure has been described in detail, the foregoing description is in all aspects illustrative and not restrictive. It is understood that numerous unillustrated modifications can be devised.

Embodiments can freely be combined with each other and can be modified or omitted as appropriate.

### EXPLANATION OF REFERENCE SIGNS

1 base plate, 2 insulating substrate, 2a front circuit pattern, 2b ceramic substrate, 3 semiconductor element, 8, 9 excavated portion, 10 tapered shape, 11 curved shape, 12 stepped shape, 13, 14, 15, 16 cutout portion, 100, 200, 300, 400, 500, 600, 700, 800, 900 semiconductor device.

1. An insulating substrate comprising:
a ceramic substrate; and
a circuit pattern which is joined to a front surface of the ceramic substrate and to which a semiconductor element is to be mounted, wherein
an outer peripheral portion of the circuit pattern has, on a side of a rear surface thereof joined to the ceramic substrate, an excavated portion not being in contact with the front surface of the ceramic substrate.

2. An insulating substrate comprising:
a ceramic substrate; and
a circuit pattern which is joined to a front surface of the ceramic substrate and to which a semiconductor element is to be mounted, wherein
a portion of the ceramic substrate adjacent to an outer peripheral portion of the circuit pattern has an excavated portion recessed downwards.

3. An insulating substrate comprising:
a ceramic substrate; and
a circuit pattern which is joined to a front surface of the ceramic substrate and to which a semiconductor element is to be mounted, wherein
an outer peripheral portion of the circuit pattern has a tapered shape so that the circuit pattern is tapered from a rear surface thereof joined to the ceramic substrate to a front surface thereof to which the semiconductor element is to be mounted.

4. The insulating substrate according to claim 3, wherein
the tapered shape of the outer peripheral portion of the circuit pattern is a curved shape.

5. The insulating substrate according to claim 3, wherein
the tapered shape of the outer peripheral portion of the circuit pattern is a stepped shape.

6. An insulating substrate comprising:
a ceramic substrate; and
a circuit pattern which is joined to a front surface of the ceramic substrate and to which a semiconductor element is to be mounted, wherein
an outer peripheral portion of the circuit pattern has a plurality of successive cutout portions.

7. The insulating substrate according to claim 6, wherein
the cutout portions are each rectangular, triangular, stepped, or arcuate in top view.

8. The insulating substrate according to claim 6 or 7, wherein
the circuit pattern comprises a plurality of circuit patterns, and
a length between adjacent cutout portions of the outer peripheral portion of each of the circuit patterns is shorter than a length between adjacent circuit patterns.

9. A semiconductor device comprising:
the insulating substrate according to claim 1;
the semiconductor element mounted to a front surface of the circuit pattern; and
a base plate joined to a side of a rear surface of the ceramic substrate.

10. The insulating substrate according to claim 7, wherein
the circuit pattern comprises a plurality of circuit patterns, and
a length between adjacent cutout portions of the outer peripheral portion of each of the circuit patterns is shorter than a length between adjacent circuit patterns.

11. The semiconductor device comprising:
the insulating substrate according to claim 2;
the semiconductor element mounted to a front surface of the circuit pattern; and
a base plate joined to a side of a rear surface of the ceramic substrate.

12. The semiconductor device comprising:
the insulating substrate according to claim 3;
the semiconductor element mounted to a front surface of the circuit pattern; and
a base plate joined to a side of a rear surface of the ceramic substrate.

13. The semiconductor device comprising:
the insulating substrate according to claim 4;
the semiconductor element mounted to a front surface of the circuit pattern; and
a base plate joined to a side of a rear surface of the ceramic substrate.

14. The semiconductor device comprising:
the insulating substrate according to claim 5;
the semiconductor element mounted to a front surface of the circuit pattern; and
a base plate joined to a side of a rear surface of the ceramic substrate.

15. The semiconductor device comprising:
the insulating substrate according to claim 6;
the semiconductor element mounted to a front surface of the circuit pattern; and
a base plate joined to a side of a rear surface of the ceramic substrate.

16. The semiconductor device comprising:
the insulating substrate according to claim 7;
the semiconductor element mounted to a front surface of the circuit pattern; and
a base plate joined to a side of a rear surface of the ceramic substrate.

17. The semiconductor device comprising:
the insulating substrate according to claim 8;
the semiconductor element mounted to a front surface of the circuit pattern; and
a base plate joined to a side of a rear surface of the ceramic substrate.

18. The semiconductor device comprising:
the insulating substrate according to claim 10;
the semiconductor element mounted to a front surface of the circuit pattern; and
a base plate joined to a side of a rear surface of the ceramic substrate.
